(19) United States
(12) Patent Application Publication
(10) Pub. No.: US 2008/0180176 A1
(43) Pub. Date: Jul. 31, 2008

(54) Sequential bias-controlled high power amplifier apparatus and method

(75) Inventor: Jong-Sung Lee, Yongin-si (KR)

Correspondence Address: DOCKET CLERK, P.O. DRAWER 800889, DALLAS, TX, 75380, US

(73) Assignee: Samsung Electronics Co., Ltd., Suwon-si (KR)

(21) Appl. No.: 12/012,153

(22) Filed: Jan. 30, 2008

(30) Foreign Application Priority Data
Jan. 30, 2007 (KR) 2006-0009341

(51) Int. Cl. H03F 3/04; H03G 3/20

(52) U.S. Cl. 330/297; 330/136

(57) ABSTRACT

A bias-controlled high power amplifier apparatus and method is provided. The apparatus includes a controller, a switching unit, and a power amplifier. The controller supplies a gate voltage of a power amplifier and after a delay for a predetermined time period, supplies a power source to a switching unit. The switching unit connects a drain terminal of the power amplifier with a Direct Current (DC) power source supply unit, receives a power source from the controller, and provides a drain voltage of the power amplifier to the drain terminal. The power amplifier receives the gate voltage and the drain voltage and amplifies a signal.

### CROSS-REFERENCE TO RELATED APPLICATION(S) AND CLAIM OF PRIORITY

This application claims priority under 35 U.S.C. §119(a) to a Korean Patent Application filed in the Korean Intellectual Property Office on Jan. 30, 2007 and assigned Serial No. 2007-9341, the contents of which are herein incorporated by reference.

### TECHNICAL FIELD OF THE INVENTION

The present invention relates generally to a bias-controlled high power amplifier apparatus and method, and in particular, to a high power amplifier apparatus and method for sequentially biasing a gate terminal voltage and a drain terminal voltage.

### BACKGROUND OF THE INVENTION

At present, high-power amplifiers are used in the final output stages of base stations and mobile stations used in mobile communication systems. Lateral Diffused Metal Oxide Semiconductor Field Effect Transistors (LDMOSFETs) are widely used in the high power amplifiers. However, a high frequency band and an increase of a frequency bandwidth have lead to the advent of high-power amplifiers using gallium arsenic (GaAs), gallium nitride (GaN), and the like. A description of a bias control of a high-power amplifier (HPA) using semiconductor devices such as GaAs and GaN is made below with reference to FIG. 1 showing a conventional technology.

FIG. 1 is a block diagram illustrating a high power amplifier apparatus according to the conventional art.

Referring to FIG. 1, the high power amplifier apparatus includes a power amplifier (PA) 101, a first direct-current (DC) power supply unit 103, a second DC power supply unit 105, an inductor 107, a first capacitor 109, and a second capacitor 111.

The first DC power supply unit 103 connects to a gate terminal of the power amplifier 101 and supplies a gate power source (Vgs) to the gate terminal. The gate power source (Vgs) is a voltage between a gate and a source. The second DC power supply unit 105 connects to a drain terminal of the power amplifier 101 and supplies a drain power source (Vds) to the drain terminal. The drain power source (Vds) is a voltage between a drain and the source.

The power amplifier 101 using an LDMOSFET receives a gate power source (Vgs) and a drain power source (Vds) and operates irrespective of bias sequence of the two power sources. However, the power amplifier 101 using a GaAs or GaN device receives a drain power source (Vds) after receiving a gate power source (Vgs) and operates. In other words, the power amplifier 101 using the GaAs or GaN has to receive a positive (+) power source at the drain terminal after receiving a negative (−) power source at the gate terminal in a sequential fashion because of a device characteristic.

The inductor 107 connects to the second DC power supply unit 105 and the drain of the power amplifier 101 and delays and supplies the drain power source (Vds) to the drain terminal of the power amplifier 101. That is, the drain power source (Vds) is delayed and supplied as a drain power source of the power amplifier 101 because of a physical property of the inductor 107. The inductor 107 is generally used when a consumed current is small.

The first capacitor 109 in front or rear of the power amplifier 101 cuts off a DC component such that a DC power source is not supplied to a gate terminal input circuit. The second capacitor 111 cuts off a DC component such that a DC power source is not supplied to a drain terminal output load circuit. A load unit 113, a load resistor, takes charge of Radio Frequency (RF) output.

However, in the conventional art, when the inductor 107 is used at the drain terminal to delay a power source, an RF characteristic or current capacity problem can occur. That is, when the inductor 107 is used at a drain power supply part of the power amplifier 101 in FIG. 1, a parasitic component can be generated from the inductor 107, affecting RF performance of the power amplifier 101. Also, because most chip inductors have a current capacity of about hundreds of milliamperes (mA) to 1 ampere (A), a current capacity problem can occur in an amplifier power source circuit through which several amperes flow at the time the power amplifier 101 operates.

Thus, there is needed a bias-controlled high power amplifier apparatus and method as a solution to generation of a parasitic component caused by the use of an inductor and a current capacity problem of several amperes, at the time of supplying a bias of a power amplifier using GaAs or GaN.

### SUMMARY OF THE INVENTION

To address the above-discussed deficiencies of the prior art, it is a primary aspect of the present invention to substantially solve at least the above problems and/or disadvantages and to provide at least the advantages below. Accordingly, one aspect of the present invention is to provide a bias-controlled high power amplifier apparatus and method.

Another aspect of the present invention is to provide a sequential bias-controlled high power amplifier apparatus and method for supplying or controlling a gate terminal voltage and a drain terminal voltage.

A further aspect of the present invention is to provide a sequential bias-controlled high power amplifier apparatus and method for providing a solution to generation of a parasitic component caused by the use of an inductor and a current capacity problem of several amperes, at the time of supplying a bias of a high power amplifier.

The above aspects are achieved by providing a sequential bias-controlled high power amplifier apparatus and method.

According to one aspect of the present invention, there is provided a bias-controlled high power amplifier apparatus. The apparatus includes a controller, a switching unit, and a power amplifier. The controller supplies a gate voltage of a power amplifier and after a delay for a predetermined time period, supplies a power source to a switching unit. The switching unit connects a drain terminal of the power amplifier with a Direct Current (DC) power source supply unit, receives a power source from the controller, and provides a drain voltage of the power amplifier to the drain terminal. The power amplifier receives the gate voltage and the drain voltage and amplifies a signal.

According to another aspect of the present invention, there is provided a bias-controlled high power amplification method. The method includes supplying a gate voltage of a power amplifier; after a delay for a predetermined time period, operating a switch and connecting a DC power supply unit with a drain terminal of the power amplifier; receiving a drain power source from the DC power supply unit by a switching operation; and receiving the gate voltage and the drain voltage and amplifying a signal.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a block diagram illustrating a high power amplifier apparatus according to the conventional art;

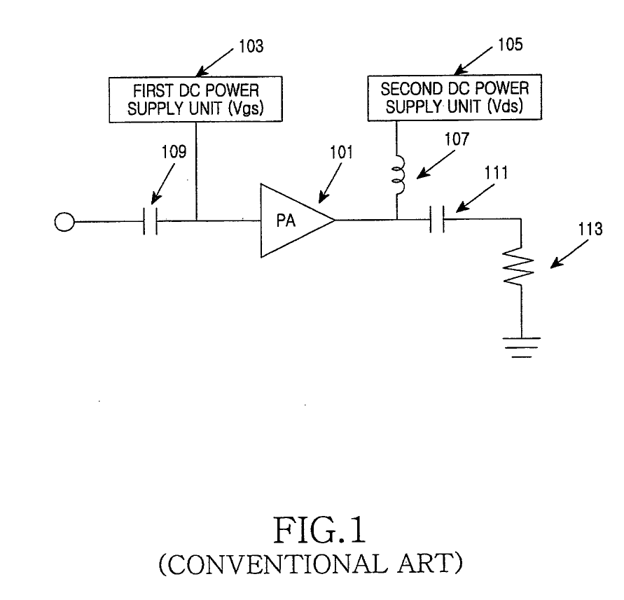

FIG. 2 is a block diagram illustrating a high power amplifier apparatus according to an exemplary embodiment of the present invention;

FIG. 3 is a diagram illustrating a bias relationship between a gate power source and a drain power source for operating a high power amplifier apparatus according to the present invention; and

FIG. 4 is a flow diagram illustrating a bias control for operating a high power amplifier apparatus according to an exemplary embodiment of the present invention.

### DETAILED DESCRIPTION OF THE INVENTION

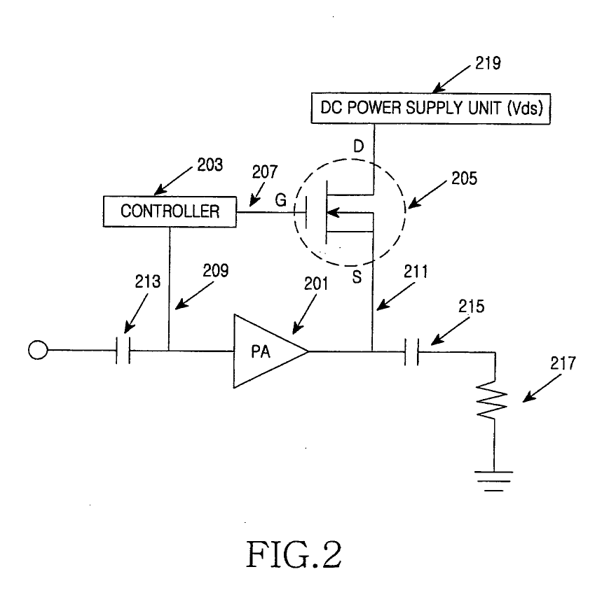

FIGS. 2 through 4, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged high power amplifier system.

A high power amplifier apparatus and method using a GaAs or GaN device for sequentially biasing a gate terminal voltage and a drain terminal voltage according to the present invention is described below.

FIG. 2 is a block diagram illustrating a high power amplifier apparatus according to an exemplary embodiment of the present invention.

Referring to FIG. 2, the high power amplifier apparatus includes a Power Amplifier (PA) 201, a controller 203, a power source MOSFET 205, a first capacitor 213, a second capacitor 215, a DC power supply unit 219, and a load resistor 217.

The DC power supply unit 219 connects with a drain (D) terminal of the power source MOSFET 205 and supplies a drain power source (Vds) to a drain terminal 211 of the power amplifier 201.

The power source MOSFET 205 has three terminals of a drain (D), a source (S), and a gate (G). The power source MOSFET 205 receives a power source (Vgs) at a gate (G) terminal 207 and operates under the control of the controller 203. In other words, when receiving a gate voltage (Vgs) at the gate (G) and a drain voltage (Vds) at the drain (D), the power source MOSFET 205 operates because the gate voltage (Vgs) causes a flow of a drain current (Id) through the drain (D). Thus, at the time the power source MOSFET 205 operates, the drain power source (Vds) from the DC power supply unit 219 is supplied to the drain terminal 211 of the power amplifier 201.

The controller 203 controls a bias of the power amplifier 201 such that the gate power source (Vgs) and the drain power source (Vds) are supplied to the gate terminal 209 and the drain terminal 211 of the power amplifier 201 in a sequential fashion, respectively. In other words, the controller 203 supplies a turn-on signal to the gate terminal 207 of the power source MOSFET 205 after supplying a power source to the gate terminal 209 of the power amplifier 201, to supply the drain power source (Vds) of the DC power supply unit 219 to the drain terminal 211 of the power amplifier 201.

Thus, through a replacement of an inductor for delaying a drain voltage of a high power amplifier by the power source MOSFET 205 of FIG. 2, the present invention can have an endurable current capacity of up to tens of amperes because of a device characteristic of the MOSFET without a high frequency parasitic component caused by the inductor. The power source MOSFET 205 can implement an accurate bias control because it is controlled under the control of the controller 203 operating according to a program.

The first capacitor 213 in front or rear of the power amplifier 201 cuts off a DC component such that a DC power source is not supplied to a gate terminal 209 input circuit. The second capacitor 215 cuts off a DC component such that a DC power source is not supplied to a drain terminal 211 output load circuit. The load resistor 217 receives power from the power amplifier 201.

The description of the power source MOSFET 205 has been made in FIG. 2 assuming that the power source MOSFET 205 is an N-channel MOSFET. However, the power source MOSFET 205 can be also a P-channel MOSFET. Also, an insulation gate type FET (MOSFET) can be replaced with a junction type FET.

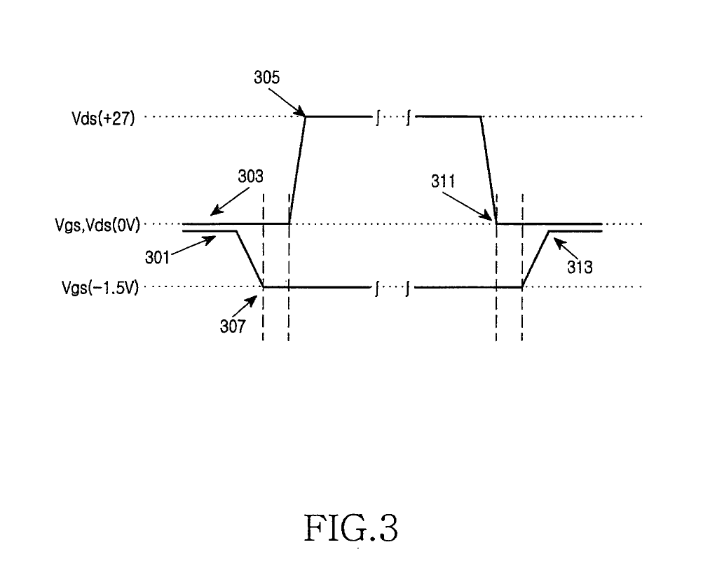

FIG. 3 is a diagram illustrating a bias relationship between a gate power source and a drain power source for operating a high power amplifier apparatus according to the present invention.

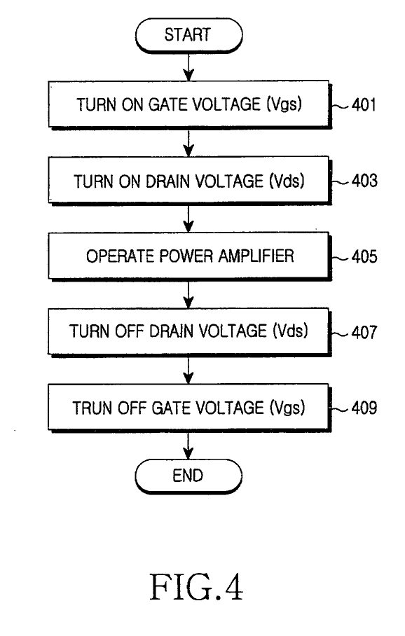

Referring to FIG. 3, in cases where a bias of a power amplifier is supplied, after a gate power source (Vgs) is first supplied as a negative power source (−1.5 V) (307) in an initial state 301 of 0 volt, a drain power source (Vds) is supplied as a positive power source (+27 V) (305) in an initial state 303 of 0 volt. Inversely, in cases where a power source of the power amplifier turns off, after the drain power source (Vds) first turns off to 0V (311), the gate power source (Vgs) turns off to 0V (313). If the drain power source (Vds) is first supplied or the gate power source (Vgs) first turns off, the power amplifier does not perform amplification because of its electrical short. Therefore, the power amplifier has to operate according to a bias sequence of FIG. 4.

FIG. 4 is a flow diagram illustrating a bias control for operating the high power amplifier apparatus according to an exemplary embodiment of the present invention.

Referring to FIG. 4, the high power amplifier apparatus turns on a gate voltage (Vgs) of the power amplifier to amplify a normal RF signal in step 401.

After that, the high power amplifier apparatus turns on a gate voltage of an MOSFET controlling a drain voltage (Vds) of the power amplifier, thereby turning on the drain voltage (Vds) of the power amplifier in step 403.

Next, the high power amplifier apparatus operates the power amplifier and amplifies an RF signal in step 405.

After operating the power amplifier, the high power amplifier apparatus turns off the drain voltage (Vds) to cut off a power source in step 407.

Next, the high power amplifier apparatus turns off the gate voltage (Vgs) in step 409.

After that, the high power amplifier apparatus terminates a process of controlling or supplying a sequential bias.

As described above, the present invention can replace an inductor by an MOSFET at the time a bias of a power amplifier is supplied, thereby preventing RF performance from being deteriorated because of a parasitic component caused by the inductor. Also, the present invention can control a power source using a power source MOSFET, thereby overcoming a current capacity limit that can occur when a broadband amplifier is realized.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A bias-controlled high power amplifier apparatus, comprising:
a controller for supplying a gate voltage of a power amplifier and after a delay for a predetermined time period, supplying a power source to a switching unit;
the switching unit for connecting a drain port of the power amplifier with a Direct Current (DC) power source supply unit, receiving a power source from the controller, and providing a drain voltage of the power amplifier to a drain terminal; and
the power amplifier for receiving the gate voltage and the drain voltage and amplifying a signal.

2. The apparatus of claim 1, wherein when operation of the power amplifier is terminated, the controller forcibly cuts off the drain voltage and the gate voltage.

3. The apparatus of claim 1, wherein the switching unit is realized by a Field Effect Transistor (FET).

4. The apparatus of claim 1, wherein the power amplifier is comprised of a gallium arsenic (GaAs) or a nitride gallium (GaN).

5. The apparatus of claim 1, further comprising a first capacitor for cutting off a DC component at a gate terminal of the power amplifier.

6. The apparatus of claim 1, further comprising a second capacitor for cutting off a DC component at the drain terminal of the power amplifier.

7. The apparatus of claim 1, wherein the controller is realized by a Field-Programmable Gate Array (FPGA).

8. The apparatus of claim 1, further comprising a load resistor for receiving power from the power amplifier.

9. A bias-controlled high power amplification method, comprising:
supplying a gate voltage of a power amplifier;
after a delay for a predetermined time period, connecting a DC power supply unit with a drain port of the power amplifier by operating a switch;
receiving a drain power source from the DC power supply unit by a switching operation; and
receiving the gate voltage and the drain voltage, and amplifying a signal.

10. The method of claim 9, further comprising when operation of the power amplifier is terminated, forcibly cutting off the drain voltage and the gate voltage.

11. The method of claim 9, wherein the switch is realized by a Field Effect Transistor (FET).

12. The method of claim 9, wherein the power amplifier is comprised of a gallium arsenic (GaAs) or a nitride gallium (GaN).

13. The method of claim 9, further comprising cutting off a DC component at a gate terminal of the power amplifier.

14. The method of claim 9, further comprising cutting off a DC component at a drain terminal of the power amplifier.

15. The method of claim 9, further comprising receiving power from the power amplifier.
